(19) United States
(12) Patent Application Publication
(10) Pub. No.: US 2015/0115443 A1
(43) Pub. Date: Apr. 30, 2015

(54) SEMICONDUCTOR PACKAGE

(71) Applicant: SAMSUNG ELECTRO-MECHANICS CO., LTD., Suwon-Si (KR)

(72) Inventors: Kyu Hwan OH, Suwon-Si (KR); Do Jae YOO, Suwon-Si (KR)

(73) Assignee: SAMSUNG ELECTRO-MECHANICS CO., LTD., Suwon-Si (KR)

(21) Appl. No.: 14/262,314

(22) Filed: Apr. 25, 2014

(30) Foreign Application Priority Data
Oct. 31, 2013 (KR) 10-2013-0131689

(51) Int. Cl. H01L 23/12; H01L 23/48; H01L 23/34; H01L 23/00

(52) U.S. Cl. CPC H01L 23/12; H01L 24/81; H01L 23/481; H01L 24/14; H01L 24/85; H01L 23/34
USPC 257/738; 438/107

(57) ABSTRACT

There is provided a semiconductor package including a first semiconductor package including a first semiconductor chip and a first substrate on which the first semiconductor chip is mounted and in which a via hole is formed outwardly of the first semiconductor chip, a second semiconductor package including a second semiconductor chip, a second substrate, on which the second semiconductor chip is mounted and in which a through hole is formed outwardly of the second semiconductor chip, and a connection member extended from the second substrate and connected to the first substrate, and a conductive member disposed in the through hole and extended to the outside of the second substrate to be electrically connected to a first upper wiring pattern formed on the first substrate. The second substrate and the connection member are formed of a conductive material.

### CROSS-REFERENCE TO RELATED APPLICATION

This application claims the benefit of Korean Patent Application No. 10-2013-0131689 filed on Oct. 31, 2013, with the Korean Intellectual Property Office, the disclosure of which is incorporated herein by reference.

### BACKGROUND

The present disclosure relates to a semiconductor package.

As the demand for mobile electronic devices such as mobile phones and tablet PCs has recently increased, demand for compact semiconductor packages having excellent performance has increased.

Accordingly, to provide compact semiconductor packages, electronic components mounted in the semiconductor package are reduced in size so as to allow for an increase in mounting density, and integrated circuits or embedded printed circuit boards (PCBs) or the like are increasingly used.

However, in order to resolve the problem of heat generation in the semiconductor package, a sufficient area for heat dissipation has to be secured, and accordingly, restrictions in terms of providing a compact semiconductor package are inevitable.

### SUMMARY

Some embodiments of the present disclosure may provide a semiconductor package capable of efficiently dissipating heat generated in the semiconductor package to the outside.

Some embodiments of the present disclosure may also provide a semiconductor package shielding electromagnetic waves generated in the semiconductor package.

According to some embodiments of the present disclosure, a semiconductor package may include a first semiconductor package including a first semiconductor chip, and a first substrate, on which the first semiconductor chip is mounted and in which a via hole is formed outwardly of the first semiconductor chip, a second semiconductor package including a second semiconductor chip, a second substrate, on which the second semiconductor chip is mounted and in which a through hole is formed outwardly of the second semiconductor chip, and a connection member that extends from the second substrate and is connected to the first substrate, and a conductive member disposed in the through hole of the second substrate and extended to the outside of the second substrate to be electrically connected to a first upper wiring pattern formed on an upper surface of the first substrate. The second substrate and the connection member may be formed using a conductive material.

The through hole formed in the second substrate may include an insulation layer formed on a surface thereof.

The insulation layer may include silicon dioxide (SiO₂).

The second semiconductor chip may be connected to the conductive member via wire bonding.

The first upper wiring pattern may be electrically connected to a first lower wiring pattern formed on a lower surface of the first substrate, via the via hole, and a first solder ball may be attached to the first lower wiring pattern.

The connection member may be attached to a second upper wiring pattern formed on an upper surface of the first substrate.

The second upper wiring pattern may be electrically connected to a second lower wiring pattern formed on a lower surface of the first substrate through the via hole, and a second solder ball may be attached to the second lower wiring pattern.

The second solder ball attached to the second lower wiring pattern may be grounded.

The second substrate and the connection member may be formed of a metal.

The semiconductor package may further include a first molded portion that encloses space between the first semiconductor package and the second semiconductor package and a second molded portion that encloses the second semiconductor chip.

The first molded portion and the second molded portion may be formed of any one of a silicone gel, an epoxy molding compound (EMC), and polyimide.

According to some embodiments of the present disclosure, a method of manufacturing a semiconductor package, may include mounting a first semiconductor chip on an upper surface of a first substrate, on which a first upper wiring pattern and a second upper wiring pattern are formed, mounting a second semiconductor chip on a second substrate formed using a conductive material and including a connection member formed of a conductive material and a through hole, connecting the first substrate and the second substrate, forming a first molded portion to seal space between the first substrate and the second substrate, forming a via hole in the first molded portion corresponding to the through hole and the first upper wiring pattern, filling the through hole and the via hole with a conductive member, connecting the second semiconductor chip and the conductive member via wire bonding, and forming a second molded portion to seal the second semiconductor chip.

The connecting of the first substrate and the second substrate may include attaching the connection member to the second upper wiring pattern.

The method may further include forming an insulation layer on a surface of the through hole formed in the second substrate.

According to some embodiments of the present disclosure, a semiconductor package may include a first semiconductor package including a first semiconductor chip and a first substrate, on which the first semiconductor chip is mounted and in which a first through hole and a second through hole are formed outwardly of the first semiconductor chip, a second semiconductor package including a second semiconductor chip, a second substrate, on which the second semiconductor chip is mounted and in which a through hole is formed outwardly of the second semiconductor chip, and a connection member that extends from the second substrate and is connected to the first substrate, and a conductive member disposed in the through hole of the second substrate and extended to the outside of the second substrate to be filled in the first through hole formed in the first substrate. The second substrate and the connection member may be formed using a conductive material.

A portion of the connection member may be inserted into the second through hole formed in the first substrate.

The first substrate may include a first solder ball and a second solder ball attached to a lower portion thereof so as to be electrically connected to the conductive member and the connection member.

The second solder ball may be grounded.

The second substrate may include an insulation layer formed on a surface of the through hole formed in the second substrate.

The insulation layer may include silicon dioxide (SiO₂).

### BRIEF DESCRIPTION OF DRAWINGS

The above and other aspects, features and other advantages of the present disclosure will be more clearly understood from the following detailed description taken in conjunction with the accompanying drawings, in which:

FIG. 1 is a schematic cross-sectional view illustrating a semiconductor package according to an exemplary embodiment of the present disclosure;

FIGS. 2 through 7 are conceptual diagrams illustrating a method of manufacturing a semiconductor package according to an exemplary embodiment of the present disclosure; and

FIG. 8 is a schematic cross-sectional view illustrating a semiconductor package according to another exemplary embodiment of the present disclosure.

### DETAILED DESCRIPTION

Hereinafter, embodiments of the present disclosure will be described in detail with reference to the accompanying drawings. The disclosure may, however, be embodied in many different forms and should not be construed as being limited to the embodiments set forth herein. Rather, these embodiments are provided so that this disclosure will be thorough and complete, and will fully convey the scope of the disclosure to those skilled in the art. In the drawings, the shapes and dimensions of elements may be exaggerated for clarity, and the same reference numerals will be used throughout to designate the same or like elements.

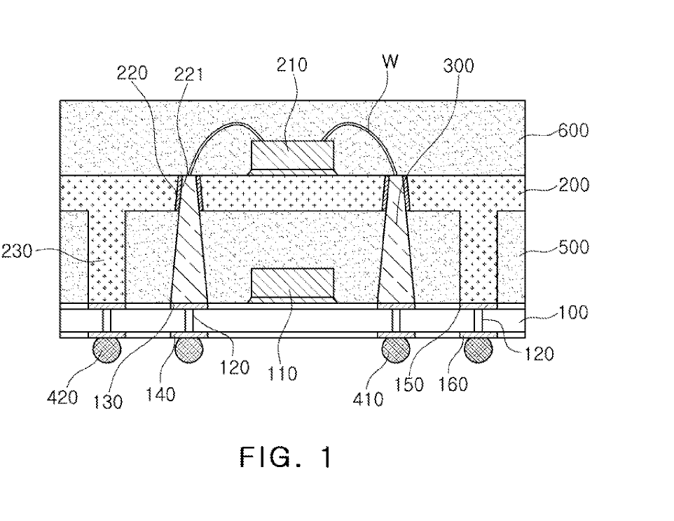

FIG. 1 is a schematic cross-sectional view illustrating a semiconductor package according to an exemplary embodiment of the present disclosure.

Referring to FIG. 1, the semiconductor package according to the exemplary embodiment of the present invention may include a first semiconductor package and a second semiconductor package.

The first semiconductor package may include a first substrate 100, a first semiconductor chip 110, a first upper wiring pattern 130, a first lower wiring pattern 140, a second upper wiring pattern 150, a second lower wiring pattern 160, and a via hole 120.

An electrical signal is transmitted between electronic components through the first substrate 100, and the first substrate 100 may be, for example, a rigid substrate, a flexible substrate, a low temperature co-fired ceramic (LTCC) substrate, a multilayer substrate, or a semiconductor mounting substrate (e.g., a ball grid array (BGA), a fine-pitch BGA (FBGA), or a tape BGA (TBGA)).

The first semiconductor chip 110 may be mounted on the first substrate 100, and the first upper wiring pattern 130 and the second upper wiring pattern 150 may be formed around the first semiconductor chip 110.

For example, the first upper wiring pattern 130 and the second upper wiring pattern 150 may be formed on an upper surface of the first substrate 100 on which the first semiconductor chip 110 is mounted.

Also, the first lower wiring pattern 140 and the second lower wiring pattern 160 may be formed on a lower surface of the first substrate 100 on positions thereof respectively corresponding to the first upper wiring pattern 130 and the second upper wiring pattern 150.

The first upper wiring pattern 130 and the first lower wiring pattern 140, and the second upper wiring pattern 150 and the second lower wiring pattern 160 may be electrically connected to each other via the via hole 120 that penetrates through the first substrate 100.

A first solder ball 410 may be attached to the first lower wiring pattern 140 to be electrically connected to an external circuit.

The second semiconductor package may include a second substrate 200, a second semiconductor chip 210, a through hole 220, and a connection member 230.

The second semiconductor chip 210 may be mounted on the second substrate 200, and the through hole 220 may be formed outwardly of the second semiconductor chip 210.

A conductive member 300 may be disposed in the through hole 220, and the conductive member 300 may extend to the outside of the second substrate 200 so as to be electrically connected to the first upper wiring pattern 130 formed on the upper surface of the first substrate 100.

The second semiconductor chip 210 may be electrically connected to the conductive member 300 via wire bonding W.

The connection member 230 may extend from the second substrate 200 to be attached to the second upper wiring pattern 150 formed on the upper surface of the first substrate 100.

The second substrate 200 and the connection member 230 may be formed of a conductive material, and may be formed of, for example, a metal such as copper (Cu) or an alloy thereof.

Accordingly, the second substrate 200 and the connection member 230 may be electrically connected to the second upper wiring pattern 150 formed on an upper surface of the first substrate 100.

The second upper wiring pattern 150 may be electrically connected to the second lower wiring pattern 160 via the via hole 120 that penetrates through the first substrate 100, and a second solder ball 420 may be attached to the second lower wiring pattern 160.

The second solder ball 420 may be grounded, and accordingly, the connection member 230 and the second substrate 200 that are electrically connected to the second solder ball 420 may also be grounded.

As the second substrate 200 is grounded, electromagnetic waves may be shielded in the semiconductor package according to the exemplary embodiment of the present disclosure.

For example, when electromagnetic waves are generated, the electromagnetic wave may affect the first semiconductor chip 110 or the second semiconductor chip 210 to cause malfunctions. Thus, the second substrate 200 may be grounded to thereby shield electromagnetic waves.

Also, as the second substrate 200 and the connection member 230 may be formed using a metal, heat generated in the semiconductor package according to the exemplary embodiment of the present disclosure may be dissipated to the outside.

For example, when the second substrate 200 and the connection member 230 are formed of a metal having relatively good thermal conductivity, heat generated in the semiconductor package according to the exemplary embodiment of the present disclosure may be dissipated to the outside and effects of efficient heat dissipation may be obtained.

Meanwhile, the through hole 220 that penetrates through the second substrate 200 may be formed in the second substrate 200.

An insulation layer 221 may be formed on a surface of the through hole 220, and the through hole 220 may have a conductive member formed therein.

As the second substrate 200 may be formed of a conductive material, electrical short circuits may be generated between the conductive member 300 disposed in the through hole 220 and the second substrate 200.

Accordingly, the insulation layer 221 is formed on the surface of the through hole 220 so as to prevent electrical connectivity between the second substrate 200 and the conductive member 300.

The insulation layer 221 may include, for example, silicon dioxide (SiO₂), but is not limited thereto, and any material capable of insulating the conductive member 300 from the second substrate 200 may be used.

A first molded portion 500 may be formed between the first semiconductor package and the second semiconductor package.

The first molded portion 500 is disposed between the first substrate 100 and the second substrate 200 to prevent electrical short circuits from occurring between the first semiconductor chip 110, the conductive member 300, and the connection member 230, and furthermore, to surround the first semiconductor chip 110, the conductive member 300, and the connection member 230 from the outside to fix the same, thereby safely protecting the first semiconductor chip 110, the conductive member 300, and the connection member 230 from external impacts.

The first molded portion 500 may cover the first semiconductor chip 110, the conductive member 300, and the connection member 230.

The first molded portion 500 is formed to cover and seal the first semiconductor chip 110, the conductive member 300, and the connection member 230, thereby protecting the first semiconductor chip 110, the conductive member 300, and the connection member 230 from an external environment.

Also, the first molded portion 500 may surround the first semiconductor chip 110, the conductive member 300, and the connection member 230 from the outside to fix the first semiconductor chip 110, the conductive member 300, and the connection member 230, thereby protecting the first semiconductor chip 110, the conductive member 300, and the connection member 230 from an external impact.

The first molded portion 500 may be formed by using a molding method, and in this case, at least one of a silicone gel, an epoxy mold compound (EMC), or polyimide, which have a relatively high thermal conductivity, may be used as a material of the first molded portion 500.

However, the embodiments of the present disclosure are not limited thereto, and other various methods such as a method of compressing a semi-cured resin may also be used to form the first molded portion 500.

Meanwhile, a second molded portion 600 that encloses the second semiconductor chip 210 may be further included in the second semiconductor package.

The second molded portion 600 may be disposed on an upper surface of the second substrate 200 to cover the second semiconductor chip 210, thereby safely protecting the second semiconductor chip 210 and wire bonding W.

The second molded portion 600 may be formed to cover and seal the second semiconductor chip 210 and the wiring bonding W, thereby protecting the second semiconductor chip 210 and the wire bonding W from external environmental conditions.

The second molded portion 600 may be formed by using a molding method, and in this case, at least one of a silicone gel, an EMC, and polyimide, which have a relatively high thermal conductivity, may be used as a material of the second molded portion 600.

However, the embodiments of the present disclosure are not limited thereto, and other various methods such as a method of compressing a semi-cured resin may also be used to form the second molded portion 600.

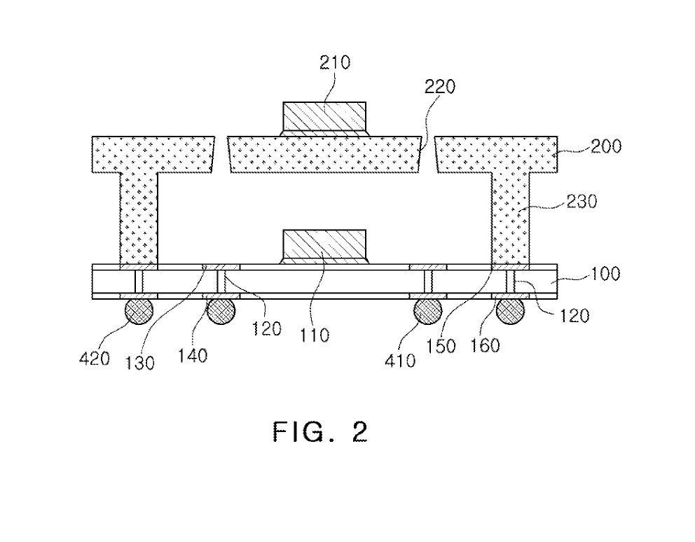

FIGS. 2 through 7 are conceptual diagrams illustrating a method of manufacturing a semiconductor package according to an exemplary embodiment of the present disclosure.

Referring to FIG. 2, first, a via hole 120 is formed in the first substrate 100, and the first upper wiring pattern 130 and the first lower wiring pattern 140 and the second upper wiring pattern 150 and the second lower wiring pattern 160 are respectively formed on an upper surface and a lower surface of the first substrate 100 to correspond to each other at positions where the via hole 120 is formed.

Also, the first semiconductor chip 110 is mounted on the first substrate 100.

The second semiconductor chip 210 is mounted on the second substrate 200, and a through hole 220 is formed in the second substrate 200 to penetrate through the second substrate 200.

Also, the first substrate 100 and the second substrate 200 are connected so that the connection member 230 extending from the second substrate 200 is attached to the second upper wiring pattern 150 formed on the upper surface of the first substrate 100.

Here, the second substrate 200 and the connection member 230 may be formed of a conductive material.

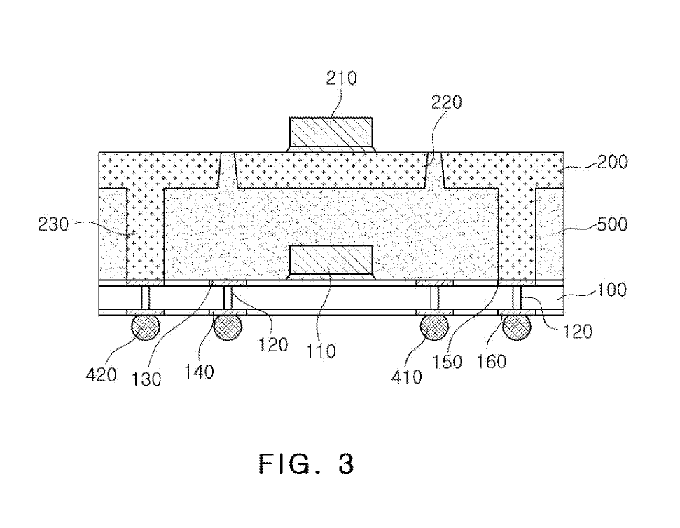

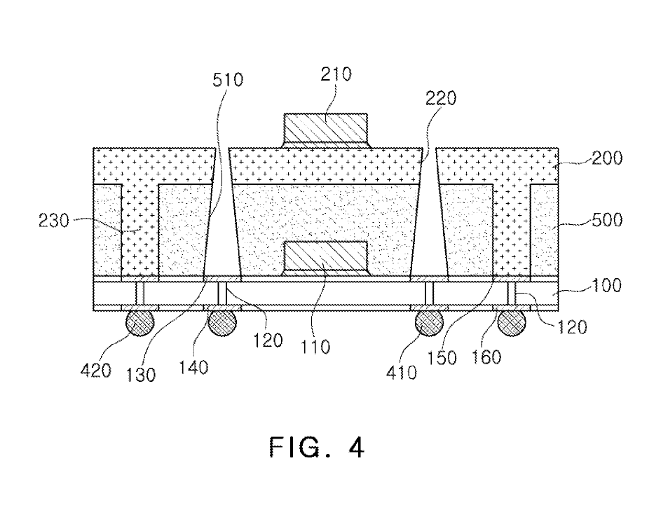

Referring to FIGS. 3 and 4, a molding resin is injected between the first substrate 100 and the second substrate 200 to form the first molded portion 500 that encloses space between the first substrate 100 and the second substrate 200.

Here, a via hole 510 is formed in the first molded portion 500 corresponding to the through hole 220 formed in the second substrate 200 and the first upper wiring pattern 130 formed on the first substrate 100.

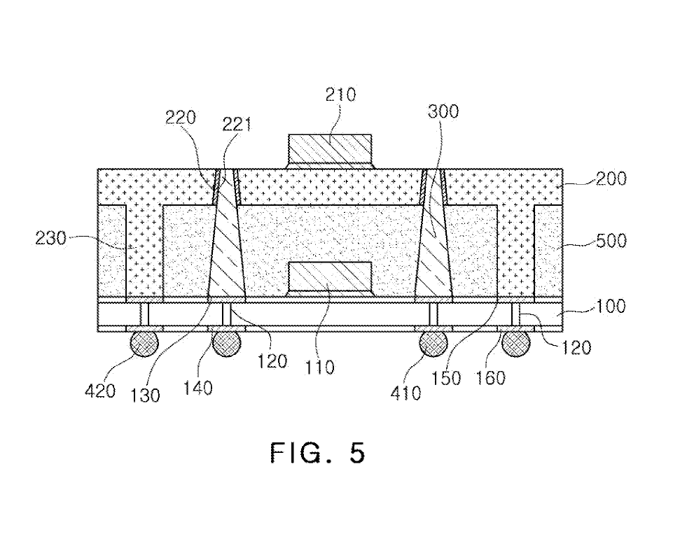

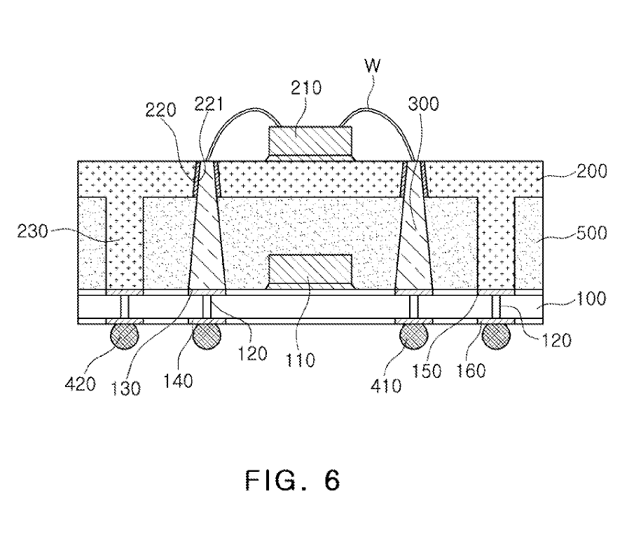

Referring to FIGS. 5 and 6, a conductive member 300 is disposed in the through hole 220 and the via hole 510 formed in the first molded portion 500, and the second semiconductor chip 210 and the conductive member 300 are electrically connected via the wire bonding W.

Here, an insulation layer 221 is formed on an surface of the through hole 220 so as to prevent electrical short circuits between the second substrate 200 formed of a conductive material and the conductive member 300 disposed in the through hole 220.

For example, the insulation layer 221 may be formed on the surface of the through hole 220 before disposing the conductive member 300 in the through hole 220, and the conductive member 300 may be disposed in the through hole 220 and the via hole 510 formed in the first molded portion 500.

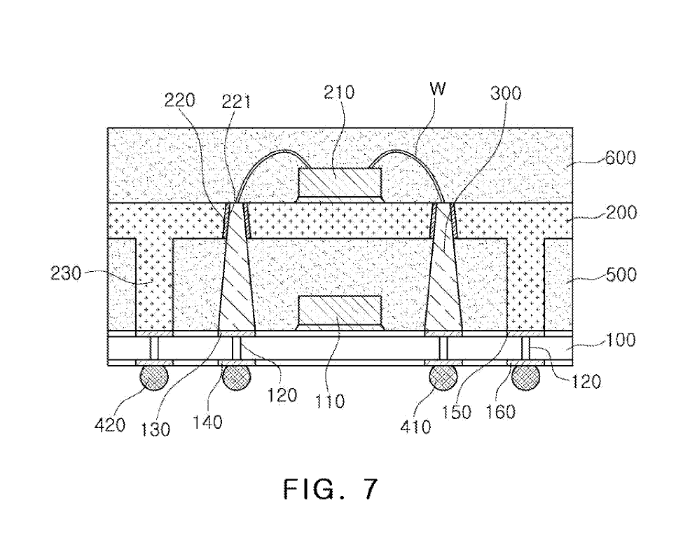

Referring to FIG. 7, a molding resin is injected into the second substrate 200 to form the second molded portion 600 that encloses the second semiconductor chip 210 and the wire bonding W.

According to the semiconductor package of the exemplary embodiment of the present disclosure, the second substrate 200 and the connection member 230 are formed using a conductive material, thereby efficiently dissipating heat generated in the semiconductor package, to the outside.

In addition, electromagnetic waves may be shielded by grounding the second substrate 200 formed using a conductive material.

Meanwhile, as the insulation layer 221 is formed on the surface of the through hole 220 formed in the second substrate 200, electrical short circuits between the conductive member 300, which functions as a signal connection terminal, and the second substrate 200 may be prevented.

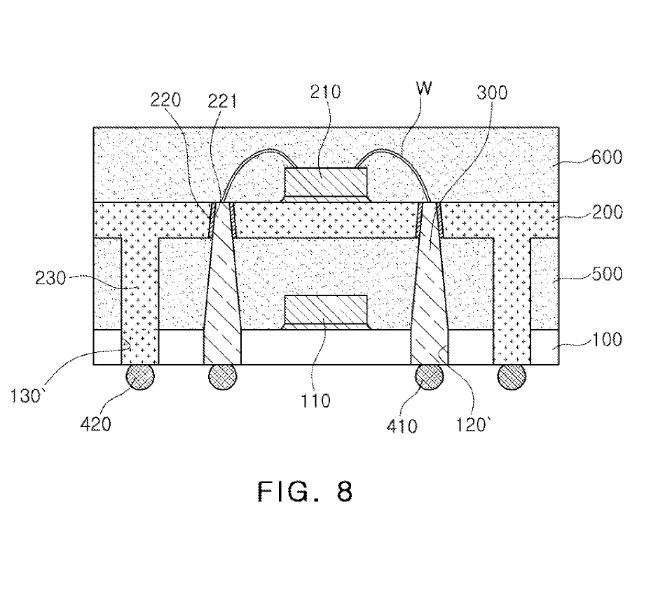

FIG. 8 is a schematic cross-sectional view illustrating a semiconductor package according to another exemplary embodiment of the present disclosure.

Referring to FIG. 8, the semiconductor package according to another exemplary embodiment of the present disclosure is the same as the semiconductor package of the exemplary embodiment of the present invention described above with reference to FIGS. 1 through 7 except for a connective relationship between a first semiconductor package and a second semiconductor package. Thus, descriptions will only focus on the connective relationship between the first semiconductor package and the second semiconductor package.

The semiconductor package according to another exemplary embodiment of the present disclosure may include a first semiconductor package and a second semiconductor package.

The first semiconductor package may include a first semiconductor chip 110 and a first substrate 100, on which the first semiconductor chip 110 is mounted and in which a first through hole 120′ and a second through hole 130′ are formed outwardly of the first semiconductor chip 110.

The second semiconductor package may include a second semiconductor chip 210, a second substrate 200, on which the semiconductor chip 210 is mounted and in which a through hole 220 is formed outwardly of the semiconductor chip 210, and a connection member 230 that extends from the second substrate 200 and is connected to the first substrate 100.

Here, a portion of the connection member 230 may be inserted into the second through hole 130′ formed in the first substrate 100.

The second substrate 200 and the connection member 230 may be formed using a conductive material, and may be formed of, for example, a metal such as Cu, an alloy thereof, or the like.

Meanwhile, a conductive member 300 may be disposed in the through hole 220, and the conductive member 300 may extend to the outside of the second substrate 200 to be disposed in the first through hole 120′ formed in the first substrate 100.

A first solder ball 410 and a second solder ball 420 may be attached to a lower portion of the first substrate 100 so as to be electrically connected to the conductive member 300 and the connection member 230.

In detail, the first solder ball 410 may be attached to the conductive member 300 disposed in the first through hole 120′, and the second solder ball 420 may be attached to the connection member 230 inserted into the second through hole 130′.

The second solder ball 420 may be grounded, and accordingly, the connection member 230 and the second substrate 200 that are electrically connected to the second solder ball 420 may also be grounded.

As the second substrate 200 is grounded, electromagnetic waves may be shielded in the semiconductor package according to another exemplary embodiment of the present disclosure.

Meanwhile, the through hole 220 that penetrates through the second substrate 200 may be formed in the second substrate 200.

An insulation layer 221 may be formed on a surface of the through hole 220, and the through hole 220 may be disposed with the conductive member 300.

As the second substrate 200 may be made of a conductive material, electrical short circuits may occur between the conductive member 300 disposed in the through hole 220 and the second substrate 200.

Accordingly, the insulation layer 221 is formed on the surface of the through hole 220 so as to prevent an electricity transfer through the second substrate 200 and the conductive member 300.

The insulation layer 221 may include, for example, silicon dioxide (SiO₂), but is not limited thereto, and any material capable of insulating the conductive member 300 from the second substrate 200 may be used.

According to the semiconductor package of the exemplary embodiments of the present disclosure, heat generated in the semiconductor package may be efficiently dissipated to the outside.

In addition, electromagnetic waves generated in the semiconductor package may be shielded.

While exemplary embodiments have been shown and described above, it will be apparent to those skilled in the art that modifications and variations could be made without departing from the spirit and scope of the present disclosure as defined by the appended claims.

What is claimed is:

1. A semiconductor package comprising:
a first semiconductor package including a first semiconductor chip, and a first substrate, on which the first semiconductor chip is mounted and in which a via hole is formed outwardly of the first semiconductor chip;
a second semiconductor package including a second semiconductor chip, a second substrate, on which the second semiconductor chip is mounted and in which a through hole is formed outwardly of the second semiconductor chip, and a connection member that extends from the second substrate and is connected to the first substrate; and
a conductive member disposed in the through hole of the second substrate and extended to the outside of the second substrate to be electrically connected to a first upper wiring pattern formed on an upper surface of the first substrate,
wherein the second substrate and the connection member are formed using a conductive material.

2. The semiconductor package of claim 1, wherein the through hole formed in the second substrate comprises an insulation layer formed on a surface of the through hole.

3. The semiconductor package of claim 2, wherein the insulation layer includes silicon dioxide (SiO₂).

4. The semiconductor package of claim 2, wherein the second semiconductor chip is connected to the conductive member via wire bonding.

5. The semiconductor package of claim 1, wherein the first upper wiring pattern is electrically connected to a first lower wiring pattern formed on a lower surface of the first substrate, via the via hole, and a first solder ball is attached to the first lower wiring pattern.

6. The semiconductor package of claim 1, wherein the connection member is attached to a second upper wiring pattern formed on an upper surface of the first substrate.

7. The semiconductor package of claim 6, wherein the second upper wiring pattern is electrically connected to a second lower wiring pattern formed on a lower surface of the first substrate through the via hole, and a second solder ball is attached to the second lower wiring pattern.

8. The semiconductor package of claim 7, wherein the second solder ball attached to the second lower wiring pattern is grounded.

9. The semiconductor package of claim 1, wherein the second substrate and the connection member are formed of a metal.

10. The semiconductor package of claim 1, further comprising a first molded portion that encloses space between the first semiconductor package and the second semiconductor package and a second molded portion that encloses the second semiconductor chip.

11. The semiconductor package of claim 10, wherein the first molded portion and the second molded portion are formed of any one of a silicone gel, an epoxy molding compound (EMC), and polyimide.

12. A method of manufacturing a semiconductor package, the method comprising:
mounting a first semiconductor chip on an upper surface of a first substrate, on which a first upper wiring pattern and a second upper wiring pattern are formed;
mounting a second semiconductor chip on a second substrate formed using a conductive material and including a connection member formed of a conductive material and a through hole;
connecting the first substrate and the second substrate;
forming a first molded portion to seal space between the first substrate and the second substrate;
forming a via hole in the first molded portion corresponding to the through hole and the first upper wiring pattern;
filling the through hole and the via hole with a conductive member;
connecting the second semiconductor chip and the conductive member via wire bonding; and
forming a second molded portion to seal the second semiconductor chip.

13. The method of claim 12, wherein the connecting of the first substrate and the second substrate includes attaching the connection member to the second upper wiring pattern.

14. The method of claim 12, further comprising forming an insulation layer on a surface of the through hole formed in the second substrate.

15. A semiconductor package comprising:
a first semiconductor package including a first semiconductor chip, and a first substrate, on which the first semiconductor chip is mounted and in which a first through hole and a second through hole are formed outwardly of the first semiconductor chip;
a second semiconductor package including a second semiconductor chip, a second substrate, on which the second semiconductor chip is mounted and in which a through hole is formed outwardly of the second semiconductor chip, and a connection member that extends from the second substrate and is connected to the first substrate; and
a conductive member disposed in the through hole of the second substrate and extended to the outside of the second substrate to be disposed in the first through hole formed in the first substrate,
wherein the second substrate and the connection member are formed using a conductive material.

16. The semiconductor package of claim 15, wherein a portion of the connection member is inserted into the second through hole formed in the first substrate.

17. The semiconductor package of claim 15, wherein the first substrate comprises a first solder ball and a second solder ball attached to a lower portion of the first substrate so as to be electrically connected to the conductive member and the connection member.

18. The semiconductor package of claim 17, wherein the second solder ball is grounded.

19. The semiconductor package of claim 15, wherein the second substrate comprises an insulation layer formed on a surface of the through hole formed in the second substrate.

20. The semiconductor package of claim 19, wherein the insulation layer includes silicon dioxide (SiO₂).
